(19) United States
(12) Patent Application Publication
(10) Pub. No.: US 2026/0286526 A1
(43) Pub. Date: Sep. 24, 2026

(54) CHAMBER FOR BACKSIDE DEPOSITION

(71) Applicant: Applied Materials, Inc., Santa Clara, CA (US)

(72) Inventors: Hyun Joo LEE, Santa Clara, CA (US); Pranav Vijay GADRE, Santa Clara, CA (US); Sathya Swaroop GANTA, Sunnyvale, CA (US); HyoJin KIM, San Jose, CA (US); Dmitry LUBOMIRSKY, Cupertino, CA (US)

(21) Appl. No.: 19/088,266

(22) Filed: Mar. 24, 2025

(51) Int. Cl. C23C 16/458; C23C 16/455; C23C 16/46; C23C 16/505

(52) U.S. Cl. CPC C23C 16/4586; C23C 16/45565; C23C 16/46; C23C 16/505

(57) ABSTRACT

An embodiment of a semiconductor processing system includes a chamber body having a central axis, a heater positioned in the chamber body, a showerhead positioned in the chamber body axially below the heater along the central axis, the showerhead having a top surface. In addition, the semiconductor processing system includes a processing volume defined axially between the heater and the top surface of the showerhead along the central axis. Further, the semiconductor processing system includes a capture ring spaced axially above the top surface of the showerhead within the processing volume. The capture ring includes a support ledge that is configured to support a substrate such that a backside of the substrate is exposed to the showerhead through the capture ring.

### BACKGROUND

Embodiments disclosed herein generally relate to methods and apparatus for processing a substrate. More specifically, embodiments disclosed herein are directed towards methods and apparatus for deposition or etching a backside of a substrate.

The fabrication of microelectronic devices may involve a complicated process sequence including hundreds of individual processes performed on semi-conductive, dielectric, and conductive substrates. Examples of these processes include oxidation, diffusion, ion implantation, thin film deposition, cleaning, etching, and lithography, among others. Such processes may be time consuming and expensive and may involve the use of multiple processing chambers.

### SUMMARY

Some embodiments disclosed herein are directed to a semiconductor processing system including a chamber body having a central axis, a heater positioned in the chamber body, and a showerhead positioned in the chamber body axially below the heater along the central axis. The showerhead has a top surface. In addition, the semiconductor processing system includes a processing volume defined axially between the heater and the top surface of the showerhead along the central axis. Further, the semiconductor processing system includes a capture ring spaced axially above the top surface of the showerhead within the processing volume. The capture ring including a support ledge that is configured to support a substrate such that a backside of the substrate is exposed to the showerhead through the capture ring.

Some embodiments disclosed herein are directed to a method of depositing a film on a backside of a substrate that includes introducing a substrate into a process chamber. In addition, the method includes lowering the substrate onto a capture ring that is positioned in a processing volume of the process chamber, wherein the capture ring has a top side and a bottom side, wherein the top side faces a heater within the processing volume and the bottom side faces a showerhead within the processing volume, and wherein the capture ring is supported on and spaced above the showerhead by a plurality of spacer pins. Further, the method includes contacting the backside of the substrate with energized particles through the capture ring to deposit the film on the backside.

Some embodiments disclosed herein are directed to a semiconductor processing system including a chamber body having a central axis, a heater positioned in the chamber body, wherein the heater is axially movable within the chamber body along the central axis, and a showerhead positioned in the chamber body and axially spaced from the heater. In addition, the semiconductor processing system includes a pumping liner positioned in the chamber body that extends circumferentially about the central axis. The showerhead and the heater are at least partially axially received within the pumping liner so that a processing volume is defined within the pumping liner axially between the heater and the showerhead. Further, the semiconductor processing system includes a capture ring positioned in the processing volume. The capture ring is suspended between the heater and the showerhead on a plurality of spacer pins that are engaged with the showerhead and the capture ring, and the capture ring is configured to support a substrate in the processing volume so that a backside of the substrate is exposed to energized particles emitted from the showerhead.

### BRIEF DESCRIPTION OF THE DRAWINGS

For a detailed description of various exemplary embodiments, reference will now be made to the accompanying drawings in which:

FIG. 1 is a schematic, partial cross-section of a process chamber for performing a backside deposition process according to some embodiments;

FIG. 2 is a top view of a capture ring for use in the process chamber of FIG. 1 according to some embodiments;

FIG. 3 is a side view of the capture ring of FIG. 2 according to some embodiments;

FIG. 4 is a cross-sectional view of the capture ring taken along section A-A in FIG. 2 according to some embodiments;

FIG. 5 is a cross-sectional view of the capture ring supported above a showerhead of the process chamber of FIG. 1 via a plurality of spacer pins along section B-B in FIG. 2 according to some embodiments;

FIG. 6 is a schematic top view illustrating the engagement between one of the spacer pins and a slot defined in the capture ring of FIG. 2 according to some embodiments;

FIG. 7 is a top view of a plenum plate of the showerhead in the process chamber of FIG. 1 according to some embodiments; and

FIG. 8 is a flow diagram of a method of depositing a film onto a backside of a substrate.

### DETAILED DESCRIPTION

The fabrication of microelectronic devices may include a large number of individual processes performed on semiconductor, dielectric, and conductive substrates. Among these processes, the fabrication operation may include the deposition of one or more layers on the substrate. As the number of layers increases, film stress and substrate bowing becomes more of an issue. Specifically, film deposition and other processing techniques used in forming the devices typically occur on one side of the substrate (such as a top side). As the deposited layers build up on this single side of the substrate, they can introduce stress in the substrate that causes the substrate to undesirably bow or deform. Substrate bowing may cause feature alignment issues in subsequent processing steps which thereby results in defects.

One solution for correcting substrate bow is to deposit additional material on the backside of the substrate to counteract bowing and stresses resulting from topside layer deposition. Conventional processing systems may be configured to flip a substrate in order to conduct a film deposition operation on the backside. However, flipping the substrate risks damage to the substrate and the layers/components formed thereon.

Accordingly, embodiments disclosed herein are directed to processing chambers and related methods that are configured to deposit a film onto a backside of a substrate (such as a semiconductor substrate) without flipping the substrate. For instance, in some embodiments, the processing chamber may be configured to suspend a substrate above a showerhead via a capture ring so that the backside of the substrate is exposed to process gas (which may comprise energized particles) emitted from the showerhead to facilitate the film deposition process. Some embodiments of a processing chamber may also include a gas block that is configured to selectively adjust a flow or distribution of the process gas across the backside of the substrate so as to control the deposition of the film and thus the counteraction of stress in the substrate. Thus, through use of the embodiments disclosed herein, a film may be deposited on a backside of a substrate without risking damage thereto via additional processing movements (e.g., flipping the substrate).

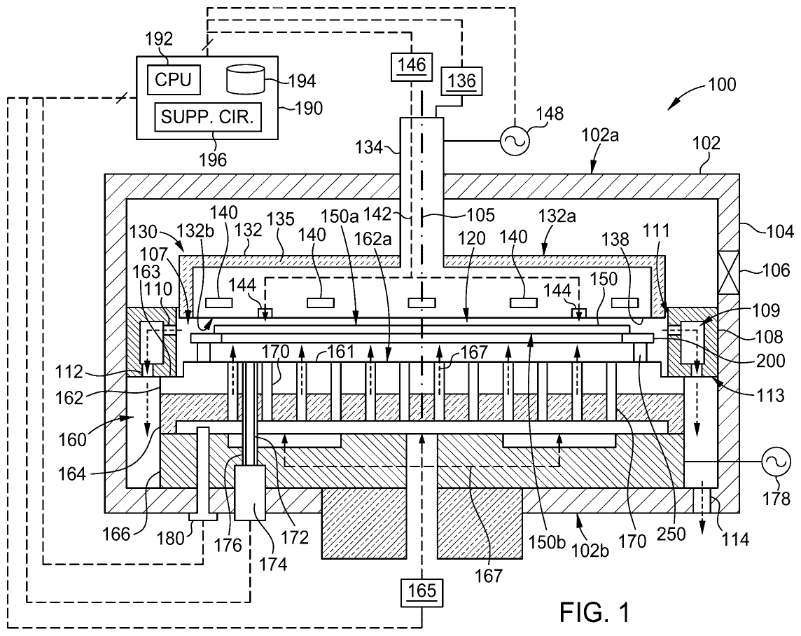

FIG. 1 illustrates a schematic cross-sectional view of a process chamber 100, according to some embodiments. The process chamber 100 is configured to perform backside deposition operations on a substrate 150 as previously described.

As used herein, a “substrate” (e.g., substrate 150) or “substrate surface,” generally refers to any substrate or substrate surface upon which processing is performed. Processing includes deposition, etching, patterning and other methods utilized during semiconductor processing. A substrate or substrate surface which may be processed may also include dielectric materials such as silicon dioxide, silicon nitride, organosilicates, and carbon doped silicon oxide or nitride materials. In certain embodiments, the substrate or substrate surface includes photoresist materials, hardmask materials, or other films or layers utilized in the patterning of a substrate. The substrate itself is not limited to any particular size or shape. Although the embodiments disclosed herein are generally described with reference to a round 200 millimeter (mm) or 300 mm substrate, other shapes, such as polygonal, squared, rectangular, curved, or otherwise non-circular substrates may be utilized according to some embodiments.

The process chamber 100 includes a chamber body 102 (or “body 102”). The body 102 has a central or longitudinal axis 105 (“axis 105”). In some embodiments, the axis 105 may be aligned (or substantially aligned) with the face of gravity, such that the axis 105 may be referred to as the “vertical axis.” In addition, the body 102 has a first or upper end 102a and a second or lower end 102b that is spaced from the upper end 102a along the axis 105. A sidewall 104 may be coupled to and extend axially between the ends 102a, 102b. The upper end 102a may include or define a lid (not specifically shown), and the lower end 102b may include or define a base (not specifically shown) of the body 102.

A substrate transfer passage 106 is defined on the sidewall 104. The transfer passage 106 may include a slit valve door (not shown) that is configured to provide access into and out of the chamber body 102 for the substrate 150 during operations. A transfer robot or other suitable device or system (not shown) may be used to transport the substrate 150 into and out of the body 102 via the substrate transfer passage 106 during operations.

The substrate 150 has a top side 150a and a backside 150b opposite the top side 150a. Features, such as features that comprise at least a portion of a microelectronic device may be positioned (e.g., deposited, formed, mounted, etc.) on the top side 150a. Engagement with the substrate 150, such as a part of handling the substrate 150 (e.g., with transfer robot, lift pins, chucking, etc.) may be limited to the backside 150b to prevent damage to the features formed on the top side 150a. The substrate 150 may be loaded into body 102 of process chamber 100 (e.g., via transfer passage 106) with the top side 150a facing axially upward toward the upper end 102a and may be maintained in that orientation throughout all operations performed by or in the processing chamber 100. Thus, the substrate 150 is not flipped before or during operations within the processing chamber 100.

A pumping liner 108 may be positioned in the body 102. The pumping liner 108 may comprise an annular member that extends circumferentially about the axis 105 so as to define a central cavity 107. The central cavity 107 may be generally cylindrical, in shape and may have open upper and lower ends. The pumping liner 108 may also define an annularly shaped exhaust plenum 109 that is positioned radially outward and circumferentially around the central cavity 107. The exhaust plenum 109 may be configured to collect fluids that are exhausted away from the substrate 150 during operations. A plurality of inlets 110 may be defined on a radially inner surface 111 of the pumping liner 108 that are configured to direct fluid flowing out of the central cavity 107 and into the exhaust plenum 109. In addition, a plurality of outlets 112 may be defined on an axially lower surface 113 of the pumping liner 108 that are configured to direct fluid flow out of the exhaust plenum 109 and toward an exhaust port 114 (or a plurality of exhaust ports) of the body 102. In some embodiments, the exhaust port(s) 114 may be defined in the lower end 102b of the body 102 and/or the sidewall 104 (e.g., such as along the sidewall 104, proximate the lower end 102b). The pumping liner 108 may be in fluid communication with a vacuum pump (not shown) via the exhaust port(s) 114 such that fluid (e.g., gas) may be removed from the body 102 during operations. The pumping liner 122 may be constructed from ceramic, a metal (e.g., aluminum), or some combination thereof.

A heater 130 is positioned in the body 102 such that the heater 130 is positioned axially above the substrate 150. In some embodiments, the heater 130 includes a cylindrically shaped body 132 that is coupled to or defined on a stem 134. The stem 134 may extend axially through (or may be coupled to) the upper end 102a of the body 102 relative to the axis 105. Thus, the body 132 may be suspended on and projected into the body 102 via the stem 134.

The stem 134 may be coupled to an actuation system 136 (e.g., electric motor(s), linear actuator(s), etc.) that is configured to move the stem 134 and body 132 axially within the body 102 relative to axis 105. Thus, the heater 130 may be axially (or vertically) movable within the body 102 so that the proximity between the heater 130 and the substrate 150 may be adjusted during operations.

The body 132 may include a first or upper side 132a and a second or lower side 132b that is opposite the upper side 132a. The upper side 132a may be coupled to the stem 134 and the lower side 132b may axially face the substrate 150 within the body 102. In addition, the body 132 may include a dielectric portion 135 that at least partially surrounds an outer periphery or circumference of the body 132 and at least a portion of the upper side 132a. In some embodiments, the upper side 132a and outer circumference of the body 132 may also include a grounded shield (not shown). In some embodiments, the dielectric portion 135 may also cover at least a portion of the stem 134.

The lower side 132b of body 132 may define a process-facing surface 138. The process-facing surface 138 may comprise a radially extending planar surface that may be adjacent to the top side 150a of the substrate 150 during operations. The process-facing surface 138 may be sized so as to radially cover or occlude an entirety of the top side 150a of substrate 150 within the body 102. Specifically, a diameter (or radial width) of the process-facing surface 138 may be greater than or equal to an outer diameter (or radial width) of the substrate 150.

A plurality of heating devices 140 may be positioned in the body 132 and proximate to the process-facing surface 138. During operations, the heating devices 140 may be configured to emit heat that is then transferred (such as convectively transferred and/or radiatively transferred) to the top side 150a of substrate 150 via the process-facing surface 138. The heating devices 140 may comprise electrically resistive heaters or any other suitable device that is configured to emit heat during operations. During operations, the heating devices 140 may be configured to heat the substrate 150 (specifically the top side 150 a) to a temperature of about 400° C. to about 650° C.; however, other temperatures or temperature ranges are contemplated.

The heating devices 140 may be arranged in any suitable pattern on the body 132 (such as along the lower side 132b). For instance, in some embodiments, the heating devices 140 may be arranged in one or more (e.g., a plurality of) concentric zones that are annularly arranged about the axis 105. When so arranged, the heating devices 140 may be configured to selectively heat different concentric and radially adjacent areas along the substrate 150 during operations. Still other arrangements or patterns for the heating devices 140 (e.g., a grid pattern) are contemplated.

One or more fluid flow paths 142 may be defined in the heater 130 (such as in the body 132 and the stem 134) that are configured to route non-process fluid out of one or more ports 144 defined in the process-facing surface 138 during operations. The non-process fluid may comprise a purge gas that is configured to sweep process fluid away from the top side 150a of substrate 150 as described in more detail herein. The purge gas may be routed from a suitable source 146 via the one or more fluid flow paths 142. The source 146 may be located outside of the body 102. In some embodiments. The purge gas may comprise an inert gas (e.g., nitrogen, helium, argon, etc.).

The heater 130 may also include one or more electrical grounds (such as a plurality of grounds) that are coupled to variable capacitors (not shown). The variable capacitors may be configured to enable tuning of plasma in the body 102 during operations.

The heater 130 may also be coupled to a radio frequency (RF) power source 148. The RF power source 148 may make the heater 130 (or one or more portions thereof) RF hot for maintaining the plasma in the body 102 (or a portion or region therein). The heater 130 may have a dual RF zone, such as inner and outer zones, for some applications (e.g., such as high stress film deposition processes). Still other configurations of such RF zones are contemplated.

Referring still to FIG. 1, a showerhead 160 is positioned in the body 102, axially below the heater 130. The showerhead 160 includes a gas distribution plate 162, a blocker plate 164 and a plenum plate 166 (or “gas box”) stacked upon one another along the axis 105 within body 102. In some embodiments, the gas distribution plate 162, blocker plate 164, and plenum plate 166 may all comprise generally cylindrically shaped members. The blocker plate 164 is disposed axially between the gas distribution plate 162 and the plenum plate 166. A plurality of gas ports 170 may extend axially through the gas distribution plate 162 and blocker plate 164, that are configured to emit process gas during operations. Specifically, process gas 167 is introduced into the plenum plate 166 and then distributed through the gas holes 170. In some embodiments, the gas distribution plate 162, the blocker plate 164, and the plenum plate 166 may all be constructed from a metallic material (such as aluminum); however, other materials or material combinations are contemplated.

The process gas 167 may comprise a plasma that is provided from a remote plasma source (RPS) 165 positioned outside of the body 102. Thus, process gas 167 may be referred to herein as “plasma” 167. Specifically, the RPS 165 energizes a process gas and outputs the resulting plasma to the plenum plate 166, which distributes the plasma among the plurality of gas ports 170 as previously described. As will be described in more detail herein, the plenum plate 166 may include one or more fluid flow paths or channels defined therein that are configured to selectively adjust a distribution of plasma across the plurality of gas ports 170 during operations. Such adjustment of the plasma distribution may allow for more selective deposition on the backside 150b of substrate 150 so as to achieve a desired reduction (or counteraction) of internal stresses or deformation therein. Additional gas sources, such as carrier gas or other non-process gases, may also be in fluid communication with the gas ports 170 of showerhead 160. For instance, a source of carrier gas (e.g., an inert gas such as argon (Ar), helium (He), etc.) may be coupled to the gas ports 170 (e.g., either together with or separate from the RPS 165) in some embodiments.

The gas distribution plate 162 may include a stepped upper surface. Specifically, the gas distribution plate 162 may have an upper end 162a that includes a planar top surface 161 and an annular surface 163. The top surface 161 may be radially centered along the axis 105, and the annular surface 163 may be axially spaced from (e.g., axially lower than) the top surface 161 and may extend circumferentially about the top surface 161 relative to axis 105. The plurality of gas ports 170 may extend through the top surface 161 and may be arranged in any suitable pattern along the top surface 161. Thus, in some embodiments, the annular surface 163 may not include any of the gas ports 170 (or other gas ports). Both the top surface 161 and the annular surface 163 may comprise planar surfaces that extend radially relative to the axis 105.

As shown in FIG. 1, the top surface 161 of showerhead 160 may be at least partially received axially into the central cavity 107 defined by the pumping liner 108. The heater 130, and specifically the body 132 of the heater 130, may be axially received into the central cavity 107 axially above the showerhead 160. Thus, a processing volume 120 may be defined in the central cavity 107, axially between the heater 130 (specifically the process-facing surface 138 of body 132) and the showerhead 160 (specifically the top surface 161). As will be described in more detail herein, the substrate 150 may be received in the processing volume 120 during the backside deposition or etching process.

The showerhead 160 also includes a plurality of lift pins 172 (only one of which is shown in FIG. 1). The lift pins 172 are coupled to a lift assembly 174. The lift pins 172 extend through the gas distribution plate 162, the blocker plate 164, and the plenum plate 166. The lift assembly 174 is at least partially positioned below the plenum plate 166. The lift assembly 174 is configured to move the lift pins 172 axially (or vertically) to thereby lift or lower the substrate 150 out of or into, respectively, the processing volume 120 during operations.

The lift pins 172 may be disposed in dielectric sleeves 176. In some embodiments, the lift assembly 174 has three lift pins 172; however, other numbers of lift pins 172 are contemplated. The lift pins 172 may be positioned so as to extend out from and retract into the top surface 161 of the gas distribution plate 162. The lift pins 172 may each have a convex (e.g., dome) shape in the top surface that is configured to engage with the substrate 150, particularly the backside 150b of substrate 150, during operations. The lift pins 172 may be fixed from rotation to minimize abrasion and damage to the substrate 150.

The showerhead 160, such as one or more of the gas distribution plate 162, blocker plate 164, plenum plate 166, etc., may be coupled to an RF power source 178. The RF power source 178 may make the showerhead 160 (or at least a portion or component thereof) RF hot for maintaining the plasma in the processing volume 120.

A temperature probe 180 may extend into the body 102 so as to measure a temperature therein during operations. For instance, the temperature probe 180 may extend axially into the body 102 and through the gas block 168 so as to be configured to measure a temperature in the body 102 below the blocker plate 164 and thus proximate to the processing volume 120. The temperature probe 180 may comprise any suitable temperature sensing device, assembly, system, or array, such as a thermocouple, thermistor, resistive temperature sensing device, etc.

The process chamber 100 can be at least partially controlled by a processor-based system controller such as controller 190. Specifically, the controller 190 may be configured to perform operations for backside deposition on the backside 150b of substrate 150 in the process chamber 100 during operations. For example, the controller 190 may be configured to control flow of various gases via the gas sources and coordinate plasma generation and flows within the processing chamber 100. The controller 190 may also be configured to control all aspects of electric field generation within the processing chamber 100 by modulating and controlling application of voltages to one or more of the components of the showerhead 160 and heater 130 to generate an electric field within the process volume 120. The controller 190 may further operate to control various stages of a substrate process sequence.

The controller 190 includes a programmable central processing unit (CPU) 192 that is operable with a memory 194 and support circuits 196, an input control unit (not shown), and a display unit (not shown), such as power supplies, clocks, cache, input/output (I/O) circuits, and the like, coupled to the various components of the processing chamber 100 to facilitate control of the substrate processing. The controller 190 also includes hardware for monitoring substrate processing through sensors in the processing chamber 100, including sensors monitoring flow, RF power, voltage potential and the like. Sensors, such as the temperature probe 180, that measure system parameters (e.g., substrate temperature, chamber atmosphere pressure and the like), may also provide information to the controller 190.

To facilitate control of the processing chamber 100 and associated plasma and electric field formation processes, the CPU 192 may be one of any form of general purpose computer processor that can be used in an industrial setting, such as a programmable logic controller (PLC), for controlling various chambers and sub-processors. The memory 194 is coupled to the CPU 192 and the memory 194 is non-transitory and may be one or more of readily available memory such as random access memory (RAM), read only memory (ROM), floppy disk drive, hard disk, or any other form of digital storage, local or remote. The Support circuits 196 are coupled to the CPU 192 for supporting the processor in a conventional manner. The plasma and electric field formation and other processes are generally stored in the memory 194, typically as a software routine. The software routine may also be stored and/or executed by a second CPU (not shown) that is remotely located from the hardware being controlled by the CPU 192.

The memory 194 may be in the form of a computer-readable storage media that contains instructions, that when executed by the CPU 192, facilitates the operation of the processing chamber 100. The instructions in the memory 194 may be in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

In certain embodiments, the program(s) embody machine learning capabilities. Various data features include process parameters such as processing times, temperatures, pressures, voltages, polarities, powers, gas species, precursor flow rates, and the like. Relationships between the features are identified and defined to enable analysis by a machine learning algorithm to ingest data and adapt processes being performed by the processing chamber 100. The machine learning algorithms may employ supervised learning or unsupervised learning techniques. Examples of machine learning algorithms embodied by the program include, but are not limited to, linear regression, logistic regression, decision tree, state vector machine, neural network, naïve Bayes, k-nearest neighbors, K-Means, random forest, dimensionality reduction algorithms, and gradient boosting algorithms, among others. In one example, the machine learning algorithm is utilized to modulate RF power and precursor gas flow to form a plasma and then facilitate maintenance of a low ion density plasma which includes a greater concentration of radicals than ions. The formation of charges species in this manner may be refined and improved by identifying constituents of the charged species cloud (e.g. radicals and/or ions) and modifying chamber process or apparatus characteristics to form and maintain a charged species cloud which exhibits desirable characteristics as an electric field coupling medium in the processing volume 120.

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

Referring still to FIG. 1, the substrate 150 may be supported in the processing volume 120 by a capture ring 200. The capture ring 200 may comprise an annular or ring-shaped member that is further supported in the processing volume 120 and above the top surface 161 of gas distribution plate 162 of showerhead 160 via a plurality of spacer pins 250.

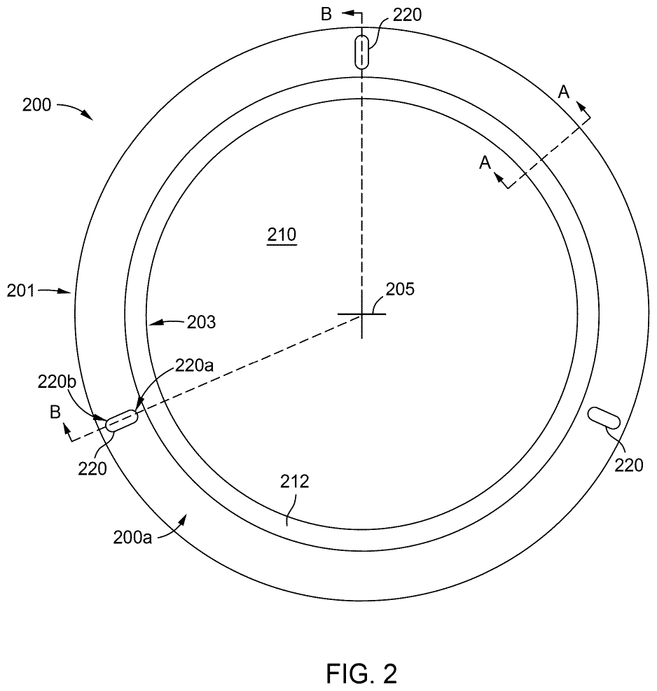

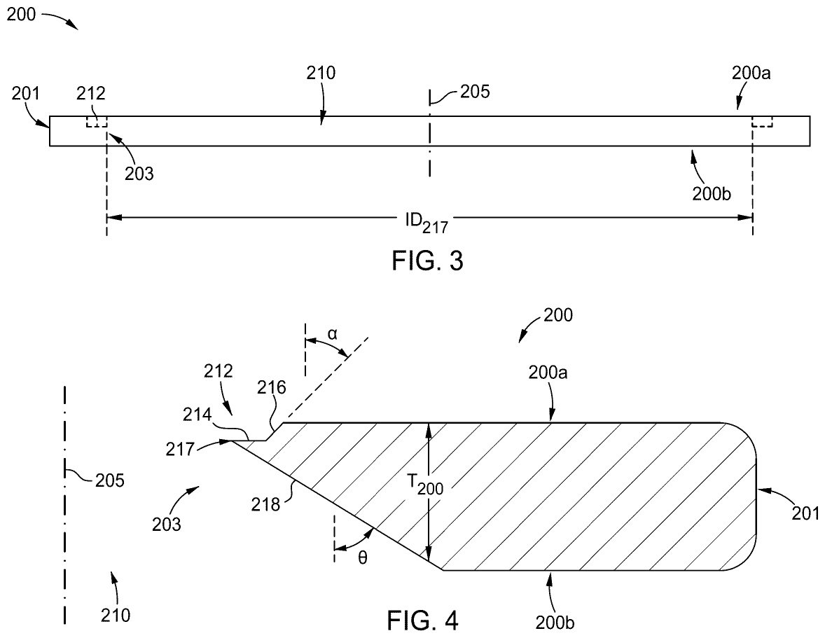

FIGS. 2 and 3 show top and side views, respectively, of the capture ring 200 according to some embodiments. In addition, FIG. 2 illustrates the position of the axis 105 of body 102 (FIG. 1) when the capture ring 200 is positioned therein. As previously described, the capture ring 200 is a ring-shaped member that includes a first or top side 200a and a second or bottom side 200b, opposite the top side 200a. As may be appreciated in FIG. 1, the top side 200a may face (such as axially face) the heater 130 and the bottom side 200b may face (such as axially face) the showerhead 160 within the processing volume 120.

In some embodiments, the capture ring 200 may be constructed from a dielectric material. For instance, in some embodiments, the capture ring 200 may be constructed from a ceramic material. However, other materials or material combinations are contemplated for the capture ring 200 in other embodiments.

Referring still to FIGS. 2 and 3, in addition, the capture ring 200 may include a radially outer side 201 and a radially inner side 203. The radially outer side 201 and radially inner side 203 may both extend circumferentially about the axis 105, with the radially outer side 201 being positioned radially outside of the radially inner side 203. The radially inner side 203 may define a central opening 210 that extends axially between the sides 200a, 200b along axis 105.

Referring briefly to FIGS. 1 and 2, the lift pins 172 may be radially inset from the radially inner side 203 of capture ring 200. As a result, the lift pins 172 may be aligned with and may extend into, the central opening 210 of capture ring 200 during operations. In some embodiments, the lift pins 172 may be concentrically arranged about the axis 105 at a radius of about 5 inches (or a diameter of about 10 inches about the axis 105); however, other spacings or arrangements are contemplated.

Referring again to FIGS. 2 and 3, a circumferential ledge 212 (or a “support ledge” 212) may be defined on the top side 200a, adjacent the radially inner side 203. As will be described in more detail herein, the ledge 212 may define a support surface for the substrate 150 (FIG. 1) during operations.

FIG. 4 shows a cross-section of the capture ring 200 taken along section A-A in FIG. 2 according to some embodiments. As shown in FIG. 4, the ledge 212 may be defined by a first frustoconical surface 216 extending from the top side 200a that is intersected with a planar surface 214 extending from the radially inner surface 203. The frustoconical surface 216 and the planar surface 214 may meet or intersect one another at a fillet (not shown) or other rounded transition. The planar surface 14 may extend radially and the frustoconical surface 216 may taper radially inward toward the axis 105 when moving from the top surface 200a at an angle α relative to axis 105. The angle α may be in a range from about 0° to about 45° such as from about 15° to about 30°. Thus, the angle α may define an acute angle relative to the axis 105.

During operations, the frustoconical surface 216 may help to ensure alignment of the substrate 150 on the ledge 212 (FIG. 1). Specifically, if the substrate 150 is radially misaligned with the ledge 212 as lift pins 172 (FIG. 1) lower the substrate 150 onto the capture ring 200, the frustoconical surface 216 may slidingly guide or deflect the substrate 150 so that it is substantially aligned with the axis 105 when it abuts the planar surface 214.

In addition, the capture ring 200 may include a chamfer (or chamfered surface) 218 defined on the bottom side 200b that tapers radially inward when moving axially toward the bottom side 200b at the angle θ relative to the axis 105. Thus, the chamfer 218 may be referred to as a frustoconical surface. In some embodiments, the angle θ may be about 75° or less. For instance, in some embodiments, the angle θ may be in a range from about 45° to about 90°, such as from about 60° to about 75°. Thus, the angle θ may define an acute angle relative to the axis 105.

The chamfer 218 may intersect with the planar surface 214 to define a radially inner edge 217 at the radially inner side 203 of the capture ring 200 that extends circumferentially about the axis 105. As a result of the chamfer 218, a thickness T₂₀₀, which may comprise an axial thickness relative to axis 105, may taper toward the inner edge 217 when moving radially toward the radially inner side 203. During operations, the chamfer 218 may help to direct process gas radially outward and away from the backside 150b of the substrate 150 within the processing volume 120 (FIG. 1).

In addition, the radially inner edge 217 may define an inner diameter (such as an “inner edge diameter”) ID₂₁₇ of the capture ring 200 (see generally in FIG. 3). In some embodiments, the inner diameter ID₂₁₇ may be in a range of from about 294 mm to about 300 mm, such as from about 296 mm to about 297 mm.

Referring back to FIG. 2, a plurality of slots 220 are defined in the capture ring 200 radially between the ledge 212 and the radially outer side 201. Each of the slots 220 may extend axially between the top side 200a and the bottom side 200b. However, in some embodiments, the slots 220 may only extend partially into the capture ring 200, such as partially into the capture ring 200 axially from the bottom side 200b. The slots 220 may each be elongated in a radial direction relative to the axis 105. Specifically, the slots 220 may each have a first or radially inner end 220a and a second or radially outer end 220b that is radially spaced from the radially inner end 220a.

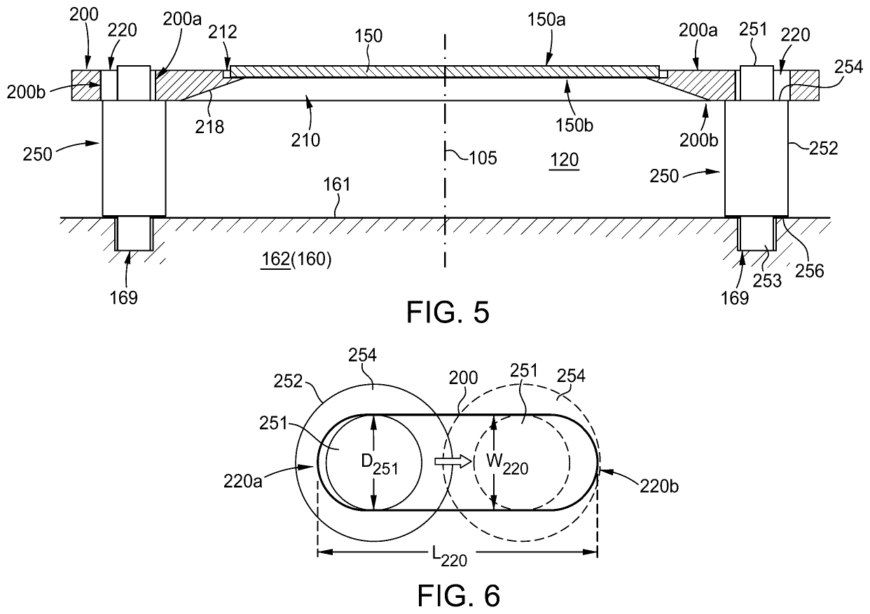

Referring now to FIG. 5, each of the slots 220 may receive a portion of a spacer pin 250 therein in order to support the capture ring 200 axially above the top surface 161 of the gas distribution plate 162 of showerhead 160. Specifically, each of the spacer pins 250 may comprise elongate members having a central cylindrical body 252 and pair of engagement projections 251, 253 extending outward from axially opposite ends of the cylindrical body 252. Each of the engagement projections 251, 253 may comprise cylindrical members that have a smaller outer diameter than the cylindrical body 252 so that a first shoulder 254 is defined between the cylindrical body 252 and a first of the engagement projections 251, and a second shoulder 256 is defined between the cylindrical body 252 and a second of the engagement projections 253.

Each of the spacer pins 250 may be engaged between the capture ring 200 and top surface 161 of the gas distribution plate 162 so that the first engagement projection 251 is inserted into a corresponding one of the slots 220 and the second engagement projection 253 is inserted into a corresponding recess 169 (or “aperture”) defined in the top surface 161. As shown in FIG. 5, the second shoulder 256 may engage or abut the top surface 161. However, in some embodiments, the second shoulder 256 may be axially spaced above the top surface 161 when the second engagement projection 253 is received into the recess 169.

As shown in FIG. 6, the outer diameter D₂₅₁ of the engagement projection 251 of each spacer pin 250 may be slightly less than a width W₂₂₀ of the corresponding slot 220. The width W₂₂₀ may be measured perpendicularly to a radial length L₂₂₀ of the slots 220 (which extends radially between the ends 220a, 220b relative to axis 105). As a result, the first shoulder 254 may be wider than the width W₂₂₀ so that the first shoulder 254 may engage or abut the bottom side 200b of the capture ring 200. Therefore, the capture ring 200 may be supported on the first shoulders 254 of spacer pins 250.

Referring now to FIGS. 5 and 6, during a deposition process on the backside 150b of substrate 150, the elevated temperature in the processing volume 120 may cause thermal expansion of one or more components positioned therein. For instance, the capture ring 200 and the gas distribution plate 162 of showerhead 160 may both experience thermal expansion during a backside deposition process. However, because the gas distribution plate 162 is constructed from a metallic material, whereas the capture ring 200 is constructed from a ceramic (or other dielectric) material, the magnitude and/or rates of thermal expansion of the capture ring 200 and the gas distribution plate 162 may be different. Specifically, the gas distribution plate 162 may experience a greater magnitude of thermal expansion than the capture ring 200.

As a result, the spacer pins 250 may be expanded (via thermal expansion) radially outward from the axis 105 (that is, along a radially oriented plane) relative to the capture ring 200 during a backside deposition operation. However, the elongated slots 220 may allow this relative radial movement of the first engagement projection 251 without causing a radial misalignment of the capture ring 200 relative to the axis 105 during operations. Specifically, as shown in FIG. 6, during a deposition process in the body 102, the relatively greater thermal expansion of the gas distribution plate 162 may cause the first engagement projection 251 to slide radially outward from the axis 105 away from the radially inner end 220a toward the radially outer end 220b of the slot 220 (see the arrow and dotted spacer pin 250 in FIG. 6). As also shown in FIG. 6, the second shoulder 254 may maintain engagement with the bottom side 200b of the capture ring 200 as the first engagement projection 251 is slid along the slot 220.

Referring again to FIG. 1, during a deposition process for depositing film on the backside 150b of the substrate, a process gas 167 may be directed to the processing volume 120 via the plenum plate 166 and ports 170 as previously described. Upon entering the processing volume 120, the process gas 167 may engage with the backside 150b of the substrate 150 via the central opening 210 in the capture ring 200 so as to facilitate film deposition thereon. The process gas 167 may then flow radially outward from the backside 150b of substrate 150 toward the inlets 110 defined in the pumping liner 108. Thereafter, the byproducts of the process gas 167 may enter the exhaust plenum 109 and exit the body 102 via the exhaust port(s) 114 as previously described. In addition, as the process gas 167 (or a byproduct thereof) is routed through the processing volume 120, the purge gas may be emitted onto the top side 150a of substrate 150 via the ports 144 in the heater 130 to prevent process gas 167 from contacting the top side 150a and therefore prevent the deposition of any films or materials on the top side 150a during operations. The purge gas may be swept out of the body 102 via the exhaust plenum 109 and port(s) 114 along with the product gas 167 (or byproduct thereof).

As previously described, and as best appreciated from FIG. 5, the radially outward flow of the process gas 167 is facilitated by the chamfer 218 of the capture ring 200. Otherwise, some portion of the process gas 167 may stagnate (e.g., via an eddy current) at or proximate to the radially inner side 203 of the capture ring 200. Such stagnation may limit the thickness of a film deposition in this region. Accordingly, by including a chamfer 218 that enhances fluid flow and reduces the risk of stagnation in these radially outer regions of the backside 150b, a more uniform deposition thickness in these regions of the backside 150b may be achieved.

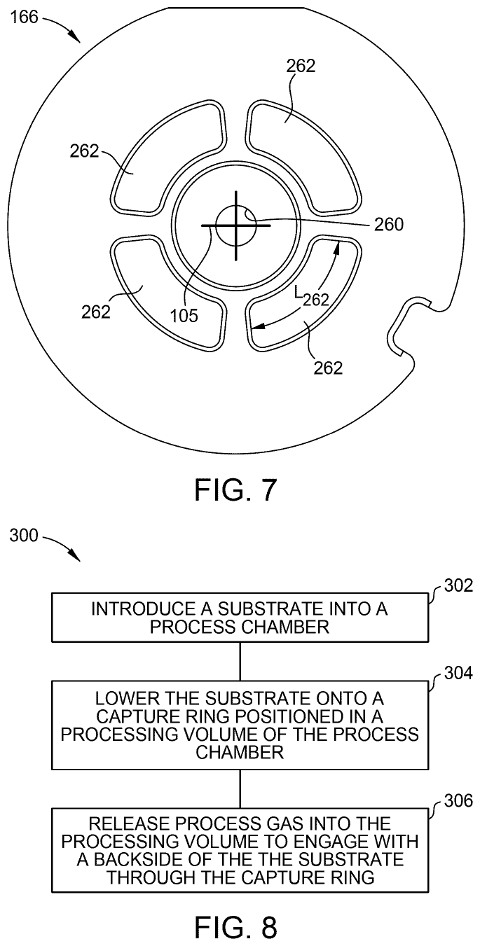

During these operations, the distribution of process gas flow through the ports 170 of the showerhead 160 may be adjusted via the flow channel(s) defined in the plenum plate 166 to provide a desired deposition thickness profile along the backside 150b of substrate 150. For instance, as shown in FIG. 7, in some embodiments, the plenum plate 166 may include a central gas channel 260 and a plurality of satellite gas channels 262 that are circumferentially arranged about the central gas channel relative to axis 105. In some embodiments, the satellite gas channels 262 may be uniformly, circumferentially spaced about the axis 105.

The central flow channel 260 may be centrally located in the plenum plate 166 so that the central gas channel 260 may extend axially through the plenum plate 166 along the axis 105. The satellite gas channels 262 may be circumferentially elongated so that each of the satellite gas channels 262 may be an arcuate (or “arcuate-shaped”) channel that extends circumferentially along an arc length L₂₆₂ (such as a circular arc length) about the axis 105. In some embodiments, each of the satellite gas channels 262 may be uniformly, circumferentially spaced (e.g., from center to center along the corresponding arc lengths L₂₆₂) about 90° from each circumferentially adjacent satellite gas channel 262 about the axis 105. Thus, in some embodiments, the plenum plate 166 may include four (4) satellite gas channels 262 circumferentially spaced about the central gas channel 262. However, it should be appreciated that different numbers, arrangements, and shapes of the gas channels 260, 262 are contemplated.

During operations, suitable flow manipulation systems or devices (e.g., valves, pumps, ports, etc.) may be adjusted (e.g., via controller 190) so as to adjust a flow rate of the process gas 167 through the central gas channel 260 and the plurality of satellite gas channels 262 and thereby adjust the relative concentrations of process gas 167 (or the relative plasma species concentration) that interacts with different regions of the backside 150b of the substrate 150. Without being limited to this or any other theory, precise control of the distribution of process gas 167 across the backside 150b of substrate 150 may allow for a film deposition thickness to be controlled to counteract a particular bow, deformation, or stress therein. In some embodiments, the ports 170 of the showerhead 160 may be arranged, organized, and configured to correspond with the central gas channel 260 and satellite gas channels 262. For instance, the ports 170 may be arranged in a plurality of groups or subsets that are aligned with one or more of the channels 260, 262.

Referring now to FIG. 8, a method 300 of depositing a film onto a backside of a substrate 150 is shown according to some embodiments. In some embodiments, the method 300 may be performed by use of the process chamber 100 and components thereof shown in FIGS. 1-7 and described herein. Thus, in describing the features of method 300, continuing reference is made to FIGS. 1-7. However, it should be appreciated that embodiments of method 300 may be performed by use of process chambers that are different from the process chamber 100 (and components thereof) shown in FIGS. 1-7.

Initially, method 300 includes introducing a substrate into a processing volume at block 302. For instance, as previously described for the process chamber 100, the substrate 150 is introduced into the body 102 of process chamber 100 via the substrate transfer passage 106. In some embodiments, the substrate 150 may be introduced into the body 102 and supported on the upper ends of the plurality of lift pins 172 (which are extended axially out of the showerhead 160 via the lift assembly 174). In some embodiments, the heater 130 may first be axially moved upward within the body 102 to accommodate the insertion of the substrate 150 therein via the substrate transfer passage 106. As previously described, the heater 130 may be moved axially within the body 102 via the actuation system 136.

In addition, method 300 includes lowering the substrate onto a capture ring positioned in a processing volume of the process chamber at block 304. For instance, as previously described for the process chamber 100, the substrate 150 may be lowered onto the ledge 212 of the capture ring 200 by retracting the lift pins 172 into the showerhead 160 via the lift assembly 174. The frustoconical surface 216 of the ledge 212 may engage with the radially outer edge (e.g., bevel) of the substrate 150 so as to center the substrate 150 onto the planar surface 214 of the ledge 212 as the lift pins 172 retract back toward the showerhead 160. Once the substrate 150 is engaged with the ledge 212, the backside 150b of the substrate 150 may be axially spaced above the top surface 161 of showerhead 160 via the capture ring 200 and the plurality of spacer pins 250 extending axially between the capture ring 200 and the gas distribution plate 162 as previously described. In addition, with the substrate 150 seated on the ledge 212 of capture ring 200, the heater 130 may be axially lowered toward to the substrate 150 via the actuation system 136 to bring the process-facing surface 138 within a desired proximity of the top side 150a of the substrate 150.

Further, method 300 includes releasing process gas into the processing volume to engage with a backside of the substrate through the capture ring at block 306. For instance, as previously described for the process chamber 100, during operations, the process gas 167 (which may include, comprise, or be converted into a plasma as previously described) may be emitted from the ports 170 in the showerhead 160 to engage with the backside 150b of the substrate 150 and facilitate the backside deposition process. During these operations, a distribution of the process gas 167 along the backside 150b may be controlled via controlling a flow through the central gas channel 260 and/or the plurality of satellite gas channels 262 defined in the plenum plate 166. The distribution of the process gas 167 along the backside 150b of the substrate 150 may be at least partially based on a desired stress or deformation relief to be applied to the substrate 150. In addition, during the backside deposition process, the capture ring 200 may prevent the process gas 167 from contacting the bevel (or sides) of the substrate 150 so as to prevent a film deposition in these regions.

Following the deposition process, the substrate may be lifted out of the processing volume and discharged from the process chamber 100. For instance, as previously described for the process chamber 100, the lift pins 172 may extend out of the showerhead 160 to engage with and lift the substrate 150 off of the ledge 212 of capture ring 200 and processing volume 120. The heater 130 may also be raised to accommodate the vertical translation of the substrate 150 out of the processing volume 120 during operations. Thereafter, the substrate 150 may be discharged out of the body 102 of process chamber 100 via the substrate transfer passage 106 (or another substrate transfer passage).

As previously described, a processing chamber according to embodiments disclosed herein may be used to deposit a film deposition on the backside (e.g., backside 150b) of a substrate in order to counteract a particular bow, deformation, or stress therein. In some embodiments, the substrate 150 may have a tensile bow so that backside 150b has a convex curvature or a compressive bow so that the backside 150b has a concave curvature.

In some embodiments, when a substrate 150 has a tensile bow, the stress (e.g., tensile stress) in the substrate 150 may be greater than 600 megapascals (MPa), such as greater than about 950 MPa and the stress shift across substrate 150 (such as from a center of the substrate 150 to the outer edge) following an annealing process at a temperature of about 450° C. for about 1 hour may be about −20 MPa to about 200 MPa, such as about −16 MPa. The film deposited on the backside 150b of substrate 150 via the process chamber 100 to counteract this tensile bow may be deposited at a rate of about 600 Angstroms per minute (A/min) to about 700 A/min, such as about 661 A/min. In addition, the deposited film may have a thickness that is less than about 1 μm, such as about 0.198 μm in some embodiments, and may have less than about 6% or less deviation in thickness uniformity (e.g., such as about 5.54% or about 3% in some embodiments). In addition, the film deposited on the backside 150b to counteract a tensile bow may cover some or all of the backside 150a. For instance, in some embodiments, the deposited film may extend from the center of the backside 150b (e.g., at the axis 105) to a radius that may be greater than 0 millimeters (mm) and less than or equal to about 149.5 mm (that is, when the substrate 150 has a total outer diameter of about 300 mm). Further, as previously described, no film may be deposited on the front side 150a via the process chamber 100. Still further, the deposited film may comprise silicon nitride (SiN) having a hardness less than about 10 Giga Pascals (GPa), or may comprise silicon dioxide (SiO₂) having a hardness that is less than about 8 GPa.

In some embodiments, when a substrate 150 has a compressive bow, the stress (e.g., compressive stress) in the substrate 150 may have a magnitude less than about 3 GPa, such as about 2.4 Gpa, and the stress shift across substrate 150 (such as from a center of the substrate 150 to the outer edge) following an annealing process at a temperature of about 650° C. for about 5 minutes (such as about 3 minutes) may be greater than about 70%, such as about 72% to about 74%, or such as about 74%. The film deposited on the backside 150b of substrate 150 via the process chamber 100 to counteract this compressive bow may be deposited at a rate of about 600 A/min to about 700 A/min, such as about 637 A/min. In addition, the deposited film may have a thickness that is less than about 1 μm, such as about 0.225 μm in some embodiments, and may have less than about 6% or less deviation in thickness uniformity (e.g., such as about 4.74 % or about 3% in some embodiments). In addition, the film deposited on the backside 150b to counteract a compressive bow may cover some or all of the backside 150a. For instance, in some embodiments, the deposited film may extend from the center of the backside 150 b (e.g., at the axis 105) to a radius that may be greater than 0 millimeters (mm) and less than or equal to about 149.5 mm (that is, when the substrate 150 has a total outer diameter of about 300 mm). Further, as previously described, no film may be deposited on the front side 150a via the process chamber 100. Still further, the deposited film may comprise SiN having a hardness less than about 10 Giga Pascals (GPa).

Embodiments disclosed herein are directed to processing chambers and related methods that are configured to deposit a film onto a backside of a substrate (such as a semiconductor substrate) without flipping the substrate. For instance, in some embodiments, the processing chamber may be configured to suspend a substrate above a showerhead via a capture ring so that the backside of the substrate is exposed to process gas (which may comprise energized particles) emitted from the showerhead to facilitate the film deposition process. Some embodiments of a processing chamber may also include a gas block that is configured to selectively adjust a flow or distribution of the process gas across the backside of the substrate so as to control the deposition of the film and thus the counteraction of stress in the substrate. Thus, through use of the embodiments disclosed herein, a film may be deposited on a backside of a substrate without risking damage thereto via additional processing movements (e.g., flipping the substrate).

The preceding discussion is directed to various embodiments. However, one of ordinary skill in the art will understand that the examples disclosed herein have broad application, and that the discussion of any embodiment is meant only to be exemplary of that embodiment, and not intended to suggest that the scope of the disclosure, including the claims, is limited to that embodiment.

The drawing figures are not necessarily to scale. Certain features and components herein may be shown exaggerated in scale or in somewhat schematic form and some details of conventional elements may not be shown in interest of clarity and conciseness.

In the preceding discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection of the two devices, or through an indirect connection that is established via other devices, components, nodes, and connections. In addition, as used herein, the terms “axial” and “axially” generally mean along or parallel to a given axis (e.g., central axis of a body or a port), while the terms “radial” and “radially” generally mean perpendicular to the given axis. For instance, an axial distance refers to a distance measured along or parallel to the axis, and a radial distance means a distance measured perpendicular to the axis. Further, when used herein (including in the claims), the words “about,” “generally,” “substantially,” “approximately,” and the like, when used to refer to a stated value, mean within a range of plus or minus 10% of the stated value.

While exemplary embodiments have been shown and described, modifications thereof can be made by one skilled in the art without departing from the scope or teachings herein. The embodiments described herein are exemplary only and are not limiting. Many variations and modifications of the systems, apparatus, and processes described herein are possible and are within the scope of the disclosure. Accordingly, the scope of protection is not limited to the embodiments described herein, but is only limited by the claims that follow, the scope of which shall include all equivalents of the subject matter of the claims. Unless expressly stated otherwise, the steps in a method claim may be performed in any order. The recitation of identifiers such as (a), (b), (c) or (1), (2), (3) before steps in a method claim are not intended to and do not specify a particular order to the steps, but rather are used to simplify subsequent reference to such steps.

What is claimed is:

1. A semiconductor processing system comprising:
a chamber body having a central axis;
a heater positioned in the chamber body;
a showerhead positioned in the chamber body axially below the heater along the central axis, the showerhead having a top surface;
a processing volume defined axially between the heater and the top surface of the showerhead along the central axis; and
a capture ring spaced axially above the top surface of the showerhead within the processing volume, the capture ring including a support ledge that is configured to support a substrate such that a backside of the substrate is exposed to the showerhead through the capture ring.

2. The semiconductor processing system of claim 1,
wherein the capture ring includes a top side and a bottom side, the top side axially facing the heater, and the bottom side axially facing the showerhead,
wherein the support ledge is defined on the top side, and
wherein the bottom side includes a chamfer such that a thickness of the capture ring tapers toward a radially inner edge of the capture ring.

3. The semiconductor processing system of claim 2, wherein the chamfer is about 60° or more relative to a radially oriented plane.

4. The semiconductor processing system of claim 1,
wherein the capture ring comprises a plurality of slots extending therein, and
wherein the capture ring is supported by a plurality of spacer pins that are inserted into the plurality of slots and engaged with the showerhead to axially suspend the capture ring above the top surface of the showerhead.

5. The semiconductor processing system of claim 4, wherein each of the plurality of slots are elongated in a radial direction relative to the central axis to accommodate a thermal expansion of the showerhead in a radial plane relative to the capture ring.

6. The semiconductor processing system of claim 1, further comprising a plenum plate positioned below the showerhead in the chamber body, wherein the plenum plate includes a central gas channel and a plurality of satellite gas channels that are circumferentially arranged about the central gas channel, wherein the central gas channel and the satellite gas channels are configured to direct processing fluid toward different portions of the showerhead.

7. The semiconductor processing system of claim 6, wherein the plurality of satellite gas channels comprises arcuate gas channels that are uniformly, circumferentially spaced about the central gas channel relative to the central axis.

8. The semiconductor processing system of claim 7, wherein the plurality of satellite gas channels comprises four arcuate gas channels that are spaced about 90° from one another about the central gas channel relative to the central axis.

9. A method of depositing a film on a backside of a substrate, the method comprising:
(a) introducing a substrate into a process chamber;
(b) lowering the substrate onto a capture ring that is positioned in a processing volume of the process chamber, wherein the capture ring has a top side and a bottom side, wherein the top side faces a heater within the processing volume and the bottom side faces a showerhead within the processing volume, and wherein the capture ring is supported on and spaced above the showerhead by a plurality of spacer pins; and
(c) contacting the backside of the substrate with energized particles through the capture ring to deposit the film on the backside.

10. The method of claim 9, further comprising:
(d) sliding the plurality of spacer pins in a plurality of slots defined in the capture ring to accommodate thermal expansion of the showerhead relative to the capture ring during (c).

11. The method of claim 9, further comprising:
(e) directing the energized particles radially away from the backside of the substrate relative to a central axis of the processing chamber along a chamfer defined on the bottom side and at a radially inner side of the capture ring.

12. The method of claim 9, further comprising:
(f) selectively adjusting a flow rate of a process gas through a central flow channel and a plurality of satellite flow channels defined in a plenum plate positioned below the showerhead, wherein the plurality of satellite flow channels are arranged circumferentially about the central flow channel; and
(g) generating the energized particles within the process chamber by use of the process gas.

13. The method of claim 9, wherein (b) comprises lowering the substrate onto the capture ring with a plurality of lift pins, and wherein the method further comprises lifting the substrate off of the capture ring after (c) with the plurality of lift pins.

14. A semiconductor processing system comprising:
a chamber body having a central axis;
a heater positioned in the chamber body, wherein the heater is axially movable within the chamber body along the central axis;
a showerhead positioned in the chamber body and axially spaced from the heater;
a pumping liner positioned in the chamber body that extends circumferentially about the central axis, wherein the showerhead and the heater are at least partially axially received within the pumping liner so that a processing volume is defined within the pumping liner axially between the heater and the showerhead; and
a capture ring positioned in the processing volume, wherein the capture ring is suspended between the heater and the showerhead on a plurality of spacer pins that are engaged with the showerhead and the capture ring, and wherein the capture ring is configured to support a substrate in the processing volume so that a backside of the substrate is exposed to energized particles emitted from the showerhead.

15. The semiconductor processing system of claim 14, wherein the capture ring has a top side that axially faces the heater and a bottom side that axially faces the showerhead, wherein the bottom side comprises a chamfer that is positioned along a radially inner edge of the capture ring that is configured to direct the energized particles radially away from the central axis within the processing volume.

16. The semiconductor processing system of claim 15, wherein the plurality of spacer pins are received within a plurality of slots defined in the capture ring, wherein each of the plurality of slots are elongated in a radial direction relative to the central axis such that plurality of spacer pins are configured to slide in the plurality of slots to accommodate a thermal expansion of the showerhead relative to the capture ring.

17. The semiconductor processing system of claim 16, further comprising a gas block positioned below the showerhead within the chamber body, wherein the gas block defines a central gas channel and a plurality of satellite gas channels circumferentially arranged about the central gas channel relative to the central axis, and wherein the central gas channel and the plurality of satellite gas channels are configured to direct the energized particles toward different portions of the showerhead.

18. The semiconductor processing system of claim 17, wherein the plurality of satellite gas channels comprises a plurality of arcuate shaped gas channels that are uniformly, circumferentially spaced about the central gas channel relative to the central axis.

19. The semiconductor processing system of claim 17, further comprising a plurality of lift pins that extend through the showerhead, wherein the plurality of lift pins are axially extendable relative to the showerhead to lift the substrate off of the capture ring.

20. The semiconductor processing system of claim 19, wherein the plurality of lift pins are positioned radially inside of a radially inner edge of the capture ring.
